(19) United States
(12) Patent Application Publication
(10) Pub. No.: US 2008/0242052 A1
(43) Pub. Date: Oct. 2, 2008

(54) Method of forming ultra thin chips of power devices

(76) Inventors: Tao Feng, Santa Clara, CA (US); Francois Hebert, San Mateo, CA (US); Ming Sun, Sunnyvale, CA (US); Yueh-Se Ho, Sunnyvale, CA (US)

Correspondence Address: CHEIN-HWA S. TSAO, 6684 MT PAKRON DRIVE, SAN JOSE, CA, 95120, US

(21) Appl. No.: 11/694,888

(22) Filed: Mar. 30, 2007

(51) Int. Cl. H01L 21/30

(52) U.S. Cl. 438/459

(57) ABSTRACT

A method for making thin semiconductor devices is disclosed. Starting from wafer with pre-fabricated front-side devices, the method includes:
Thinning wafer central portion from its back-side to produce a thin region while preserving original wafer thickness in the wafer periphery for structural strength.
Forming ohmic contact at wafer back-side.
Separating and collecting pre-fabricated devices. This further includes:
Releasably bonding wafer back-side onto single-sided dicing tape, in turn supported by a dicing frame. Providing a backing plate to match the thinned out wafer central portion. Sandwiching the dicing tape between wafer and backing plate then pressing the dicing tape to bond with the wafer.
With a step-profiled chuck to support wafer back-side, the pre-fabricated devices are separated from each other and from the wafer periphery in one dicing operation with dicing depth slightly thicker than the wafer central portion. The separated thin semiconductor devices are then picked up and collected.

### CROSS REFERENCE TO RELATED APPLICATIONS

### Field of Invention

This invention relates generally to the field of semiconductor device manufacturing. More specifically, the present invention is directed to methods to form ultra thin chips of power semiconductor devices, such as power Metal-Oxide-Semiconductor Field Effect Transistor (MOSFET) and Insulated Gate Bipolar Transistor (IGBT).

### BACKGROUND OF THE INVENTION

A general trend of modern day electronic product, as demanded by the market place, is product miniaturization with vastly increasing functionality. With no exception, the same trend also applies to the segment of power electronics. Hence, in the area of power electronics there has been an ongoing need of product miniaturization concurrent with the other requirements of efficient heat dissipation and electromagnetic interference/radio frequency interference (EMI/RFI) shielding prominent in power electronics.

As it offers advantages of bulk device electrical resistance reduction, bulk device thermal stress reduction and die stacking while maintaining low profile, the ability of making thin, less than about 10 mils, chips of power semiconductor devices is very desirable in the semiconductor industry. This is especially important in cases where an epitaxial layer has to be grown as the semiconductor bulk for High Voltage (HV) application due to high cost of thick epitaxial layers. This is because:
Required epitaxial thickness is approximately proportional to the Maximum Device Voltage.
   The following is a brief review of prior arts for making thin semiconductor wafers:

In U.S. Pat. No. 6,162,702, entitled “self-supported ultra thin silicon wafer process” Dec. 19, 2000, by Morcom et al. and assigned to Intersil Corporation, a Silicon wafer has numerous ultra thin central portions that are supported by a circumferential rim of thicker silicon was described. The central regions are thinned by conventional methods using conventional removal apparatus. As an alternative method, the central regions can also be etched out using a photoresist mask or a combination of a photoresist mask and a hard mask.

In U.S. Pat. No. 6,884,717, entitled “stiffened backside fabrication for microwave radio frequency wafers” Apr. 26, 2005, by Desalvo et al, an etching based semiconductor wafer thinning method was described as an improved alternative to grinding and polishing wafer thinning. The thinned wafer includes a structurally enhancing wafer backside grid array of original wafer thickness with grid cells surrounding individual thinned wafer areas for improvement of the strength and physical rigidity of the thinned wafer. Preferably the grid array is supplemented with an additional, wafer peripheral, backside ring also of original wafer thickness. Ability to avoid a wafer front side mounting during thinning accomplishment, fast etching, reduced wafer breakage, enhanced wafer strength and improved wafer handling achieved with the disclosed thinning arrangement all contribute to achieved advantages over conventional wafer thinning.

In US patent application 20050236693, entitled “wafer stabilization device and associated production method” Oct. 27, 2005, by Kroninger, Werner et al., a stabilization device and method were described for stabilizing a thin film wafer. The thin wafer is fixed and oriented in planar fashion. The stabilization device is a profiled ring arranged on the periphery of the wafer and is intimately connected thereto. The stabilization device and wafer are connected via negative pressure or by means of an adhesive having high thermal stability. The wafer and device are formed from similar semiconductor materials and have the same outline contour. The stabilization device remains on the wafer during process steps in the course of production and processing of the wafer.

U.S. Pat. No. 7,115,485 is entitled “method for processing wafer” Oct. 3, 2006, by Priewasser and is assigned to Disco Corporation (Tokyo, Japan). To facilitate handling a thin wafer during processing, a protective member is stuck through an adhesive agent to an outer-peripheral surplus region of a front surface of the wafer, the region being formed with no individual devices, and a back surface of the wafer is ground in a state where the whole front surface of the wafer is supported by the protective member. Since an outer periphery of the wafer is reinforced by the protective member, the wafer can be easily handled even after having been thinned by the grinding.

### SUMMARY OF THE INVENTION

A method of making complete ultra thin chips of power semiconductor devices is proposed. Starting from a semiconductor wafer of an original thickness and with pre-fabricated front-side devices, the method includes:
Thinning the wafer central portion from its back-side to provide an ultra thin region for the pre-fabricated devices while preserving the original thickness in the wafer peripheral portion for structural strength against breakage during subsequent handling.
Forming an ohmic contact at the wafer back-side.
Separating and collecting, from the wafer, each of the pre-fabricated devices into an ultra thin chip.

In an embodiment of forming the ohmic contact, the method includes:
Cleaning and etching the wafer back-side to remove dirt and oxide.
Vacuum depositing a back metal onto the wafer back-side.

In another embodiment of forming the ohmic contact, the method includes:
Ion implanting the wafer back-side with dopants to form a heavily doped conductive layer.
Annealing the wafer to activate the implanted dopants.
Cleaning and etching the wafer back-side to remove dirt and oxide.
Vacuum depositing a back metal onto the wafer back-side.

In yet another embodiment of forming the ohmic contact, the method includes:
Ion implanting the wafer back-side with dopants to form a heavily doped conductive layer.
Cleaning and etching the wafer back-side to remove dirt and oxide.
Vacuum depositing a back metal onto the wafer back-side.
Annealing the wafer to activate the implanted dopants.

In yet another embodiment of forming the ohmic contact, the method includes probing and marking the wafer front-side to distinguish functional from defective devices. Owing to a stepped topography of the wafer back-side resulting from the thinning of only its central portion, the method further uses a step-profiled chuck matching and supporting the wafer back-side topography to prevent its breakage during wafer probing. The step-profiled chuck can be further provided with vacuum through ports on its top surface to strengthen its holding power of the wafer.

In a more specific embodiment, separating and collecting the pre-fabricated devices further includes:
Temporarily bonding the wafer back-side onto a dicing tape, in a way allowing future release of the wafer under sufficient mechanical force. This is done using a single-sided tape with size larger than the wafer as the dicing tape and a dicing frame to support the dicing tape. Additionally, a backing plate is provided with size and shape substantially matching the thinned out wafer central portion. Next, with the adhesive side of the dicing tape facing the wafer back-side, sandwiching the dicing tape between the wafer and the backing plate then pressing the dicing tape into an intimate bonding relationship with the wafer back-side and adhering the tape periphery onto the dicing frame. The backing plate is then removed.
Separating the pre-fabricated devices from one another and from the wafer periphery while allowing the individual pre-fabricated devices and the wafer periphery to be bonded to the dicing tape. This is done using a step-profiled chuck matching and supporting the back-side topography of the dicing tape to prevent wafer breakage. While fixing the outer edge of the dicing tape with a dicing frame, mechanically dicing apart, with a dicing depth slightly thicker than the wafer central portion, the pre-fabricated devices from the wafer.
Next, with sufficient mechanical force, picking up and collecting the individual pre-fabricated devices from the dicing tape.

In a more specific alternative embodiment, bonding the wafer back-side onto a dicing tape in a release way is done by:
Using a double-sided tape with size larger than the wafer as the dicing tape and a dicing frame to support the dicing tape.
Providing a backing plate with its size and shape substantially matching the thinned out wafer central portion.
Sandwiching the dicing tape between the wafer and the backing plate then pressing the dicing tape into an intimate bonding relationship with both the wafer back-side and the backing plate, and adhering the tape periphery onto the dicing frame.

In a more specific embodiment, separating the pre-fabricated devices from one another and from the wafer periphery is done by:
providing a flat chuck supporting the back-side of the backing plate-dicing tape composite to prevent wafer breakage during subsequent processing steps.
While fixing the outer edge of the dicing tape with a dicing frame, mechanically dicing apart the pre-fabricated devices from the wafer.

In a more specific alternative embodiment, separating and collecting the pre-fabricated devices further includes:
Bonding the wafer front-side onto a first carrier tape in a way allowing future release. To effect future release, the first carrier tape can be made of an Ultra Violet (UV)-releasable type. Fixing the tape periphery with a dicing frame and affixing the dicing frame and the first carrier tape onto a chuck.
While fixing the outer edge of the first carrier tape with a dicing frame, separating and collecting the wafer central portion, together with the first carrier tape, from the wafer periphery.
Temporarily bonding the wafer back-side onto a second carrier tape in a way allowing future release. Fixing the outer edge of the second tape with a dicing frame and releasing the first carrier tape from the wafer so as to effect a tape transfer.
Affixing the second carrier tape onto a chuck with its outer edge fixed with a dicing frame. Separating and collecting each of the pre-fabricated devices into an ultra thin chip.

For separating the central portion from the peripheral portion of the wafer, a power laser can be employed to traverse a demarcation contour between the wafer central portion and its peripheral portion. Alternatively, a mechanical cutting head can be used in lieu of the power laser. Separating each of the pre-fabricated devices can be done by mechanically dicing apart, with a dicing depth slightly larger than the wafer thickness, the pre-fabricated devices from the wafer.

In a more specific alternative embodiment, separating and collecting the pre-fabricated devices can be done as follows:
Bonding the wafer front-side onto a carrier tape in a way allowing future release. Fixing the periphery of the carrier tape with a dicing frame and affixing the dicing frame and carrier tape onto a chuck.
Traversing scribe lines between the prefabricated devices with a power laser from the wafer backside to separate each of the pre-fabricated devices. To facilitate the navigation of the power laser, an infrared (IR) imaging camera can be deployed above the wafer backside to detect scribe lines between the prefabricated devices. Alternatively, both the dicing chuck and the dicing tape can be made of a transparent material and an imaging camera can be deployed underneath the dicing chuck and the dicing tape to detect positions of scribe lines between the prefabricated devices.
Collecting each of the pre-fabricated devices into an ultra thin chip. This can be done by transferring the separated devices onto another tape with chip back side adhered to the tape, and picking up each of the pre-fabricated devices from its front side into an ultra thin chip.

These aspects of the present invention and their numerous embodiments are further made apparent, in the remainder of the present description, to those of ordinary skill in the art.

### BRIEF DESCRIPTION OF THE DRAWINGS

In order to more fully describe numerous embodiments of the present invention, reference is made to the accompanying drawings. However, these drawings are not to be considered limitations in the scope of the invention, but are merely illustrative.

FIG. 1 illustrates a first embodiment of the overall process flow for making complete ultra thin chips of power semiconductor devices under the present invention;

FIG. 2 illustrates a second embodiment of the overall process flow for making complete ultra thin chips of power semiconductor devices under the present invention;

FIG. 3 illustrates an important next level detail of a wafer probing step of both FIG. 1 and FIG. 2;

FIG. 4A to FIG. 4C illustrate alternative embodiments for separating the central portion of the wafer from its edge ring;

FIG. 5 illustrates a first embodiment of direct wafer dicing with supportive edge ring and dicing frame; and

FIG. 6 illustrates a second embodiment of direct wafer dicing with supportive edge ring and dicing frame.

### DETAILED DESCRIPTION OF SPECIFIC EMBODIMENTS

The description above and below plus the drawings contained herein merely focus on one or more currently preferred embodiments of the present invention and also describe some exemplary optional features and/or alternative embodiments. The description and drawings are presented for the purpose of illustration and, as such, are not limitations of the present invention. Thus, those of ordinary skill in the art would readily recognize variations, modifications, and alternatives. Such variations, modifications and alternatives should be understood to be also within the scope of the present invention.

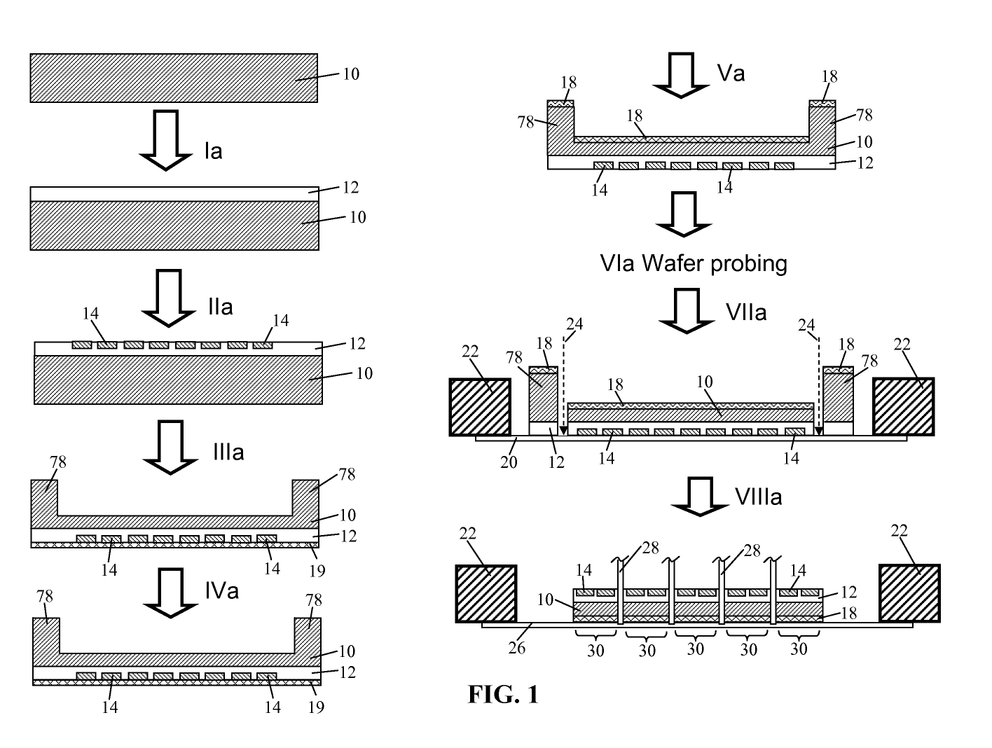

FIG. 1 illustrates a first embodiment of the overall process flow for making complete ultra thin power device chips 30 under the present invention. In this embodiment, the starting material is a wafer of an original thickness and made of a highly doped semiconductor substrate 10. The diameter of the wafer is typically in the range of from about 6″ to about 8″ although the application of the present invention is not limited to this range. Following STEP Ia, called epi growth, an epitaxial layer 12 is grown on top of the highly doped semiconductor substrate 10. Following STEP IIa, called front-side device fabrication, a plurality of fabricated devices 14 are produced on the front-side of the wafer. It is remarked that numerous methods are known in the art for front-side device fabrication. For those skilled in the art, front-side device fabrication includes photolithographic masking, dopant diffusion, ion implantation, selective pattern etching, epitaxial layer growth, material deposition.

Next, STEP IIIa, called central portion back grinding, produces a substantially thinned down central portion of the wafer vertically opposing the fabricated devices 14. STEP IIIa also leaves a peripheral portion of original thickness, called edge ring 78, for structurally supporting the central portion against breakage from subsequent process handling. This will be presently seen. The central region can be thinned by conventional mechanical methods like wafer grinding and polishing. As an alternative, the central portion can also be chemically etched thin using a photoresist mask or a combination of a photoresist mask and a hard mask. In practice, the central portion can be thinned down to a thickness of about 2˜4 mils. Notice that, just before the operation to thin the central portion, a UV-releasable dicing tape 19 is adhered to the device side of the wafer as a protective cushion. The use of UV-releasable dicing tape 19 facilitates a later tape removal/transfer following a UV (Ultra Violet) irradiation of the dicing tape. The underlying mechanism is a reduction of tackiness upon UV irradiation.

In STEP IVa, called back side clean and etch, the front-side of the wafer is protected by the UV-releasable dicing tape 19 while the back-side of the wafer is chemically cleaned and etched in preparation for receiving a metallic ohmic contact thereto. This is important as the wafer back-side must be made free of dirt and oxides for a good ohmic contact. For power semiconductor devices, back-side metal deposition is usually part of the device requirement.

In STEP Va, called back metal deposition, the now cleaned and etched back-side of the wafer is deposited with a back metal 18 suitable for forming an ohmic contact thereto. Notice that, as high temperatures are typically encountered in a metal deposition process (vacuum deposition chamber temperature is usually at least 100-150 deg C.), the UV-releasable dicing tape 19 has been removed from the wafer before back metal deposition. Otherwise the following problems could take place:

The dicing tape may not endure the high process temperature of metal deposition, or the dicing tape may outgas in the vacuum deposition chamber and affects the quality of the ohmic contact.

The back metal deposition approaches include evaporation and sputtering.

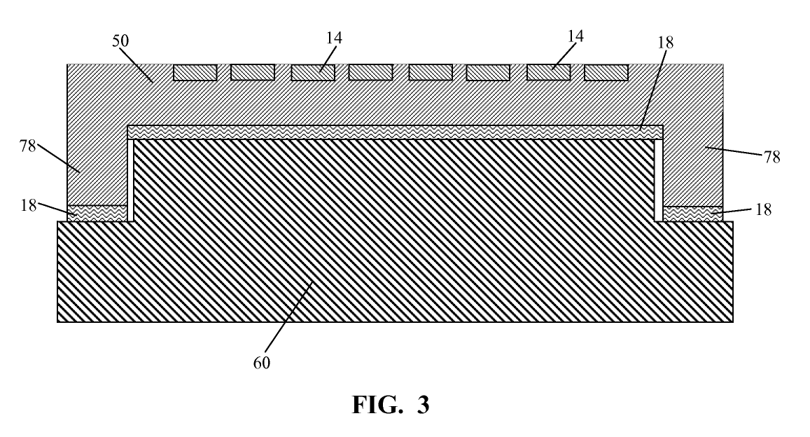

As an option, STEP Va can be followed by a STEP VIa called wafer probing. Here, the fabricated devices 14 on the front-side of the wafer are probed and marked to distinguish functional from defective devices. Some related important next level detail will be presently described in FIG. 3.

In STEP VIIa, called laser cutting, the front-side of the wafer is temporarily bonded onto a UV-releasable dicing tape one 20 with the periphery of the UV-releasable dicing tape one 20 fixed by a dicing frame 22. The dicing frame 22 together with the outer edge of the UV-releasable dicing tape one 20 are then affixed onto a chuck (not shown here for simplicity of presentation). The central portion of the wafer together with the UV-releasable dicing tape one 20 are then separated from the peripheral edge ring 78 of the wafer by traversing a demarcation contour between the central portion and the edge ring 78 with a power laser beam 24 to effect the separation.

In STEP VIIIa, called tape transfer and dicing, the now separated central portion of the back-side of the wafer is first bonded onto a dicing tape two 26 also in a way allowing future release of the wafer there from. With the outer edge of the dicing tape two 26 fixed by a dicing frame 22, release the UV-releasable dicing tape one 20 from the wafer front-side so as to effect a tape transfer. The dicing frame 22 together with the outer edge of the dicing tape two 26 are then affixed onto a chuck (not shown here for simplicity of presentation). The individual ultra thin power device chips 30 are then diced apart for collection with dicing streaks 28 produced by a corresponding dicing saw. The dicing streaks 28 should be slightly deeper than the wafer thickness for an effective device separation. Alternatively, the individual ultra thin power device chips 30 can be separated for collection with a correspondingly traversing laser beam. If a laser dicing machine with capability of dicing from the wafer back-side is employed, STEP VIIa to remove the edge ring 78 can be omitted. While not specifically illustrated here, the individual ultra thin power device chips 30 can be collected with a traversing vacuum pick up head, for example.

As illustrated in FIG. 1, the present invention discloses a process to make ultra thin (2˜4 mils) power semiconductor device chips. When applied to a vertical type of power semiconductor device such as a power MOSFET, the epitaxial layer constitutes the bulk device substrate, the source and gate of the MOSFET are located at the front-side of the wafer while the drain of the MOSFET is located at the back-side of the wafer. As an explanation, a power MOSFET is usually a vertical device with its device current flow from one major surface of the semiconductor substrate to an opposite major surface.

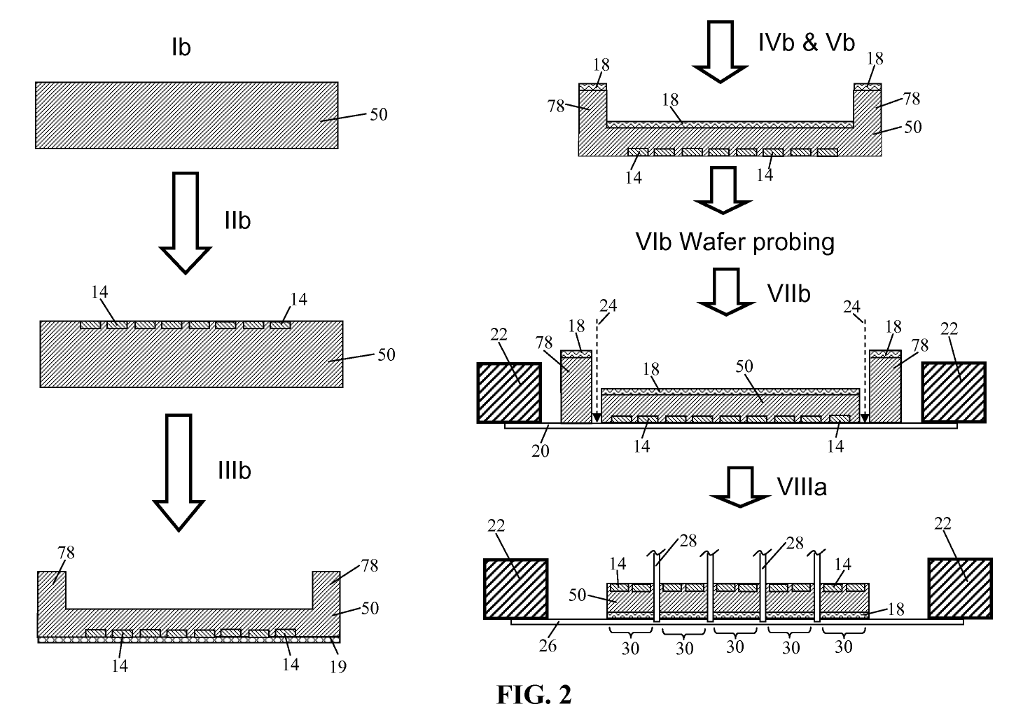

The process as illustrated in FIG. 1 is suitable for making ultra thin power semiconductor device chips with devices fabricated in epitaxial layers. FIG. 2 illustrates a second embodiment of the overall process flow for making ultra thin power device chips 30 without an epitaxial layer under the present invention. As remarked before, device for HV application may require thick epitaxial layers that are high cost. By employing material called float zone wafer, devices for HV application can be fabricated directly on the wafer without the epitaxial layer, followed by wafer thinning to a desired thickness and back metallization. The desired thickness may be between 2 to 4 mils. In this embodiment, the starting material is, following a STEP Ib called float zone wafer fabrication, a wafer of an original thickness and made of a float zone semiconductor wafer 50 that is substantially cheaper than an equivalent epitaxial layer. An example of the float zone semiconductor wafer 50 has a lightly-doped N-type bulk. Following STEP IIb, called front-side device fabrication, a plurality of fabricated devices 14 are produced on the front-side of the float zone semiconductor wafer 50. Like before, numerous methods are known in the art for front-side device fabrication.

Next, STEP IIIb, called central portion back grinding, produces a substantially thinned down central portion of the wafer vertically opposing the fabricated devices 14 and leaves a peripheral portion of original thickness, called edge ring 78, for structural support just like the previous STEP IIIa.

STEPS IVb & Vb, when taken together, serve to make an ohmic contact to the back-side of the wafer with a back metal 18 just like STEPS IVa & Va taken together. Like before, the UV-releasable dicing tape 19 has been removed from the wafer before deposition of the back metal 18. STEPS IVb & Vb encompass the following alternative procedures for making the ohmic contact:

Alternative procedure one:
(1) ion implanting the back-side of the wafer with dopants to form a heavily doped conductive layer.
(2) annealing the wafer to activate the implanted dopants.
(3) cleaning and etching the back-side of the wafer to remove dirt and oxide.
(4) vacuum evaporation or sputtering to deposit the back metal 18 onto the back-side of the wafer.
   Alternative procedure two:
(1) ion implanting the back-side of the wafer with dopants to form a heavily doped conductive layer.
(2) cleaning and etching the back-side of the wafer to remove dirt and oxide.
(3) vacuum depositing the back metal 18 onto the back-side of the wafer.
(4) annealing the wafer to activate the implanted dopants.

Except for using the low cost float zone semiconductor wafer 50, the remaining steps STEP VIb wafer probing, STEP VIIb laser cutting and STEP VIIIb dicing of FIG. 2 are respectively the same as STEPS VIa, VIIa and VIIIa of FIG. 1. To re-emphasize, the process as depicted in FIG. 2 expects to make ultra thin power device chips 30 for HV application with low cost.

FIG. 3 illustrates an important next level detail applicable to the wafer probing step of both FIG. 1 (STEP VIa) and FIG. 2 (STEP VIb). For simplicity, wafer probing geometry corresponding to FIG. 2 is illustrated here. As seen, the back-side of the wafer has a stepped topography resulting from the thinning of only its central portion from STEP IIIb. Therefore, a step-profiled chuck 60 is provided to match and support the back-side topography of the wafer to prevent its breakage during wafer probing and marking of its front-side. While not shown here to avoid obscuring details, the step-profiled chuck 60 can further include numerous vacuum ports on its top surface to strengthen its holding power of the wafer.

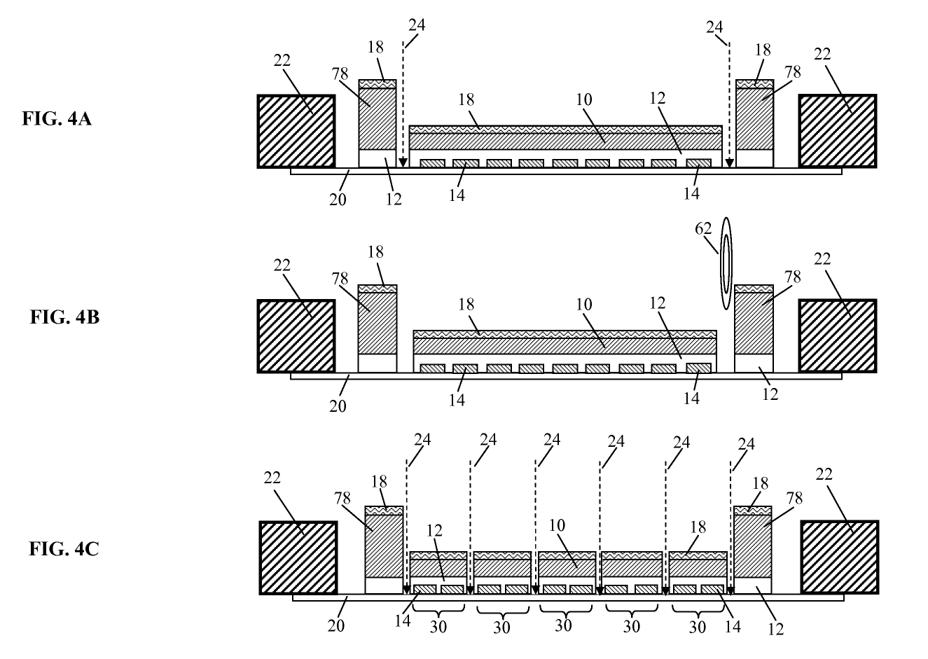

FIG. 4A to FIG. 4C illustrate alternative embodiments for separating the central portion of the wafer from its edge ring 78. For convenience of comparison, FIG. 4A repeats the same result from STEP VIIa of FIG. 1, laser cutting to separate the central portion from the peripheral edge ring 78. Instead of using the power laser beam 24, FIG. 4B illustrates traversing a demarcation contour between the central portion and the peripheral portion with a mechanical cutting head 62 to effect the separation of central portion from the peripheral portion of the wafer. In one embodiment, the mechanical cutting head 62 can be made to traverse a helical trajectory in a planetary motion with respect to the wafer. Just like in laser cutting, the UV-releasable dicing tape one 20 should be used here to facilitate tape removal/transfer afterwards through UV irradiation. Another extension of using the power laser beam 24 is, as illustrated in FIG. 4C, direct laser dicing from back-side of the wafer to separate the edge ring 78 and the individual ultra thin power device chips 30 in one step. To facilitate accurate navigation of the power laser beam 24 from the back-side, an infrared camera (not shown) can be deployed above the wafer backside to detect scribe lines between the fabricated devices 14. Alternatively, an imaging camera can be deployed underneath a transparent dicing chuck and transparent dicing tape to detect positions of scribe lines between the fabricated devices 14. As yet another variation, collecting the ultra thin power device chips 30 may further include transferring the now-separated ultra thin power device chips 30 onto another tape with chip back-side adhered to the tape, and picking up each of the ultra thin power device chips 30 from its front-side.

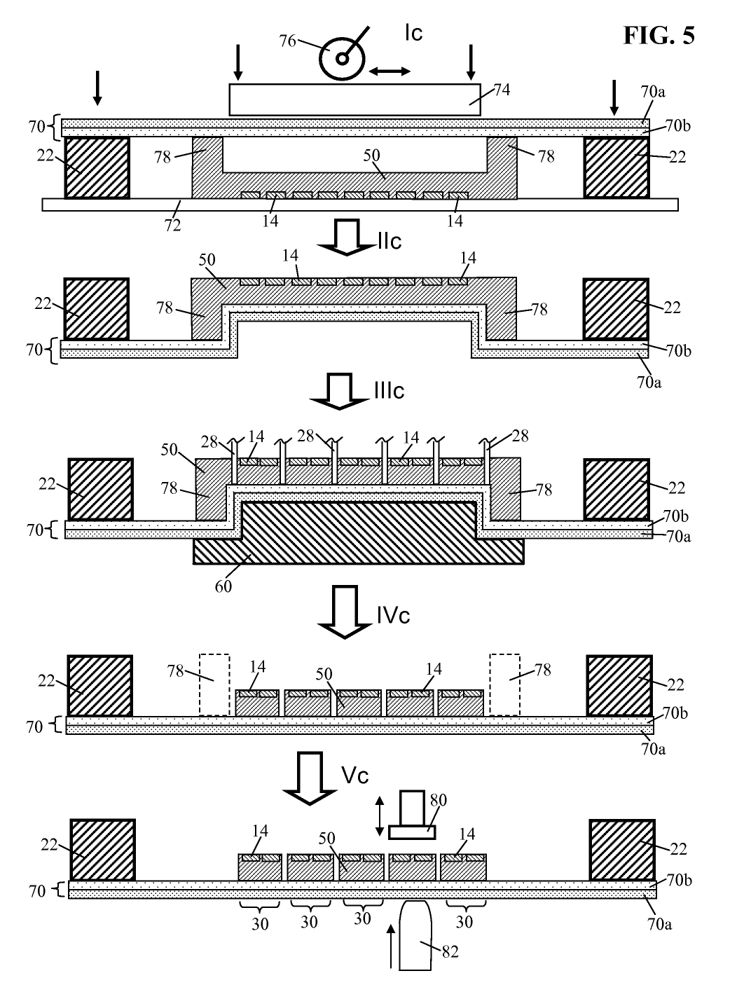

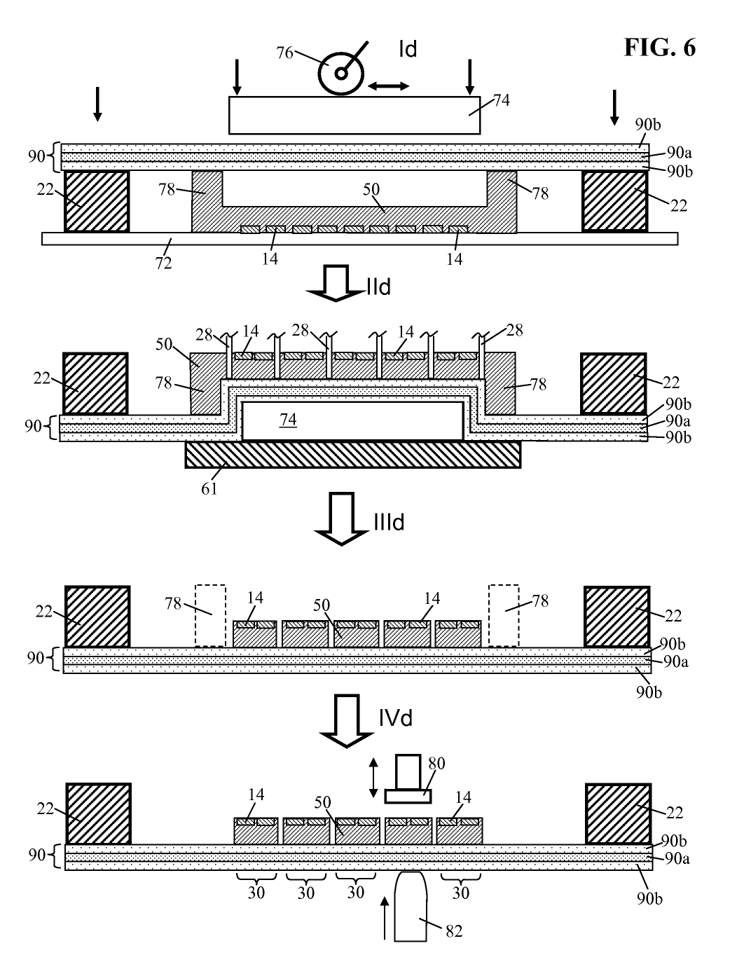

FIG. 5 and FIG. 6 illustrate embodiments of direct wafer front-side dicing into individual ultra thin power device chips 30 with supportive edge ring 78 and dicing frame 22. As will be presently illustrated, these embodiments feature the usage of conventional mechanical dicing method, direct device chip separation along scribe lines with a dicing depth slightly larger than the thickness of wafer central portion without an extra cutting step to separate the edge ring 78.

FIG. 5 illustrates a first embodiment of direct wafer front-side dicing with supportive edge ring 78 and dicing frame 22. To avoid obscuring details, the deposited back metal 18 is omitted here. In STEP Ic, a single-sided dicing tape 70 with size larger than the wafer is placed atop the back-side of edge ring 78 and the dicing frame 22. The single-sided dicing tape 70 has a tape base film 70a and a tape adhesive layer 70b. Next, a backing plate 74, with size and shape substantially matching the thinned out central portion of the wafer, is placed atop the single-sided dicing tape 70 and in full lateral alignment with the thinned out wafer central portion. The backing plate 74 and single-sided dicing tape 70 are then pressed, as illustrated with a number of down-pointing arrows, onto the wafer back-side and onto the dicing frame 22. For an intimate bonding of the single-sided dicing tape 70 onto the wafer central portion, a horizontally traversing pressure roller 76 can be applied to the top surface of the backing plate 74 as indicated. In one embodiment, the backing plate 74 can be made of a polymeric substrate with appropriate rigidity to effect the pressing action.

During the next STEP IIc, called removing backing plate and inverting wafer, the backing plate 74 is removed and the bonded assembly of wafer, single-sided dicing tape 70 and dicing frame 22 is inverted to expose the fabricated devices 14 at the top.

During the next STEP IIIc, called wafer dicing on special chuck, a step-profiled chuck 60 matching and supporting the stepped back-side topography of the single-sided dicing tape 70 is placed beneath the bonded assembly of wafer, single-sided dicing tape 70 and dicing frame 22 to support it against wafer breakage during subsequent processing steps. While not shown here to avoid obscuring details, the step-profiled chuck 60 can further include numerous vacuum ports on its top surface to strengthen its holding power of the single-sided dicing tape 70. With the outer edge of the single-sided dicing tape 70 fixed with the dicing frame 22, the fabricated devices 14 are then mechanically diced apart, with a dicing depth slightly larger than the thickness of wafer central portion, from one another and from the edge ring 78. This is illustrated with the numerous mechanical dicing streaks 28 traversing along scribe lines separating the fabricated devices 14 and the edge ring 78. Notice that the individual fabricated devices 14 and the edge ring 78 are still bonded to the single-sided dicing tape 70.

The next STEP IVc, called removing edge ring, is an optional step. With the diced wafer bonded on single-sided dicing tape 70 and the single-sided dicing tape 70 held by dicing frame 22, the separated edge ring 78 is removed from the single-sided dicing tape 70. While not essential, STEP IVc does produce a substantially flat wafer front-side topography facilitating the later pickup of individual fabricated devices 14 there from.

Finally in STEP Vc, called picking up and collecting individual pre-fabricated devices, the individual ultra thin power device chips 30 are picked up from the single-sided dicing tape 70 and collected under sufficient mechanical force from a vacuum picking up head 80. A back pushing pin 82, opposing the vacuum picking up head 80, is applied below the dicing tape to facilitate the device pick-up.

FIG. 6 illustrates a second embodiment of direct wafer front-side dicing with supportive edge ring 78 and dicing frame 22. To avoid obscuring details, the deposited back metal 18 is also omitted here. Except for the usage of a double-sided dicing tape 90 with a tape base film 90a and two tape adhesive layers 90b here, STEP Id is the same as STEP Ic. Thus, after the backing plate 74 and the double-sided dicing tape 90 are pressed onto the wafer back-side and onto the dicing frame 22, an intimate bonding of the double-sided dicing tape 90 onto both the backing plate 74 and the wafer central portion is achieved. In one embodiment, the backing plate 74 can be made of a polymeric substrate with appropriate rigidity to effect the pressing action.

During the next STEP IId, called inverting and dicing wafer on ordinary chuck, the bonded assembly of wafer, backing plate, double-sided dicing tape 90 and dicing frame 22 is simply inverted to expose the fabricated devices 14 at the top. Except for the usage of a flat chuck 61, the rest of STEP IId is the same as STEP IIIc before. This is due to the presence of the bonded backing plate 74 at the thinned out wafer central portion making up for a flat bottom topography now. After that the separated wafer edge ring and the backing plate are removed from the dicing tape. The remaining STEP IIId and STEP IVd are respectively the same as STEP IVc and STEP Vc of FIG. 5 with the exception that the tip of a back pushing pin 82 that is used to facilitate the device pick-up should be made of a non-stick material such as Teflon to avoid stuck at the double-sided dicing tape 90.

While the description above contains many specificities, these specificities should not be constructed as accordingly limiting the scope of the present invention but as merely providing illustrations of numerous presently preferred embodiments of this invention. For example, while the present invention is illustrated for ultra thin chips of power semiconductor devices, the present invention is equally applicable to many other types of semiconductor devices as well—such as digital, analog and RF devices.

Throughout the description and drawings, numerous exemplary embodiments were given with reference to specific configurations. It will be appreciated by those of ordinary skill in the art that the present invention can be embodied in numerous other specific forms and those of ordinary skill in the art would be able to practice such other embodiments without undue experimentation. The scope of the present invention, for the purpose of the present patent document, is hence not limited merely to the specific exemplary embodiments of the foregoing description, but rather is indicated by the following claims. Any and all modifications that come within the meaning and range of equivalents within the claims are intended to be considered as being embraced within the spirit and scope of the present invention.

What is claimed are:

1. A method of forming ultra thin chips of devices comprising:
a) providing a semiconductor wafer, of an original thickness, with a plurality of pre-fabricated devices located on its front-side;
b) thinning only a central portion of the wafer from its back-side to provide a corresponding ultra thin region for the pre-fabricated devices while preserving the original thickness in a peripheral portion of the wafer for structural strength against breakage during subsequent handling;
c) forming an ohmic contact at the back-side of the wafer; and
d) separating and collecting, from the wafer, each of said plurality of pre-fabricated devices into an ultra thin chip.

2. The method of forming ultra thin chips of claim 1 wherein forming an ohmic contact further comprises:
c1) cleaning and etching the back-side of the wafer to remove dirt and oxide there from; and
c2) vacuum depositing a back metal onto the back-side of the wafer.

3. The method of forming ultra thin chips of claim 1 wherein forming an ohmic contact further comprises:
c1) ion implanting the back-side of the wafer with dopants to form a heavily doped conductive layer;
c2) annealing the wafer to activate the implanted dopants;
c3) cleaning and etching the back-side of the wafer to remove dirt and oxide there from; and
c4) vacuum depositing a back metal onto the back-side of the wafer.

4. The method of forming ultra thin chips of claim 1 wherein forming an ohmic contact further comprises:
c1) ion implanting the back-side of the wafer with dopants to form a heavily doped conductive layer;
c2) cleaning and etching the back-side of the wafer to remove dirt and oxide there from;
c3) vacuum depositing a back metal onto the back-side of the wafer; and
C4) annealing the wafer to activate the implanted dopants.

5. The method of forming ultra thin chips of claim 1 wherein forming an ohmic contact further comprises probing and marking the front-side of the wafer to distinguish functional from defective devices.

6. The method of forming ultra thin chips of claim 5 wherein probing and marking the front-side of the wafer further comprises, owing to a stepped topography of the wafer back-side resulting from the thinning of only its central portion, providing a step-profiled chuck matching and supporting the back-side topography of the wafer to prevent its breakage during subsequent probing.

7. The method of forming ultra thin chips of claim 6 wherein providing a step-profiled chuck further comprises providing a plurality of vacuum ports on its top surface to strengthen its holding power of the wafer.

8. The method of forming ultra thin chips of claim 1 wherein separating and collecting the pre-fabricated devices further comprises:
d1) temporarily bonding the back-side of the wafer onto a dicing tape, in a way allowing future release of the wafer there from under sufficient mechanical force;
d2) separating the pre-fabricated devices from one another and from the peripheral portion of the wafer while allowing the bonding of the individual pre-fabricated devices and the peripheral portion of the wafer to the dicing tape; and
d3) with sufficient mechanical force, picking up and collecting the individual pre-fabricated devices from the dicing tape.

9. The method of forming ultra thin chips of claim 8 wherein temporarily bonding the back-side of the wafer onto a dicing tape further comprises:
d11) providing a single-sided tape with size larger than the wafer as the dicing tape and a dicing frame to support the dicing tape;
d12) providing a backing plate with its size and shape substantially matching the thinned out central portion of the wafer;
d13) with the adhesive side of the dicing tape facing the back-side of the wafer, sandwiching the dicing tape between the wafer and the backing plate then pressing, with assistance of the backing plate, the dicing tape into an intimate bonding relationship with the back-side of the wafer, and adhering the periphery of the tape onto the dicing frame; and
d14) removing the backing plate.

10. The method of forming ultra thin chips of claim 9 wherein separating the pre-fabricated devices from one another and from the peripheral portion of the wafer further comprises:
d21) owing to a stepped topography of the back-side of the dicing tape, providing a step-profiled chuck matching and supporting the back-side topography of the dicing tape to prevent wafer breakage during subsequent processing steps; and
d22) while fixing the outer edge of the dicing tape with a dicing frame, mechanically dicing apart, with a dicing depth slightly larger than the thickness of wafer central portion, the pre-fabricated devices from the wafer.

11. The method of forming ultra thin chips of claim 10 wherein providing a step-profiled chuck further comprises providing a plurality of vacuum ports on its top surface to strengthen its holding power of the dicing tape.

12. The method of forming ultra thin chips of claim 8 wherein temporarily bonding the back-side of the wafer onto a dicing tape further comprises:
d11) providing a double-sided tape with size larger than the wafer as the dicing tape and a dicing frame to support the dicing tape;
d12) providing a backing plate with its size and shape substantially matching the thinned out central portion of the wafer; and
d13) sandwiching the dicing tape between the wafer and the backing plate then pressing, with assistance of the backing plate, the dicing tape into an intimate bonding relationship with both the back-side of the wafer and the backing plate, and adhering periphery of the tape onto the dicing frame.

13. The method of forming ultra thin chips of claim 12 wherein separating the pre-fabricated devices from one another and from the peripheral portion of the wafer further comprises:
d21) providing a flat chuck supporting the back-side of the backing plate-dicing tape composite to prevent wafer breakage during subsequent processing steps; and
d22) while fixing the outer edge of the dicing tape with a dicing frame, mechanically dicing apart, with a dicing depth slightly larger than the thickness of wafer central portion, the pre-fabricated devices from the wafer.

14. The method of forming ultra thin chips of claim 13 wherein providing a flat chuck further comprises providing a plurality of vacuum ports on its top surface to strengthen its holding power of the backing plate-dicing tape composite.

15. The method of forming ultra thin chips of claim 1 wherein separating and collecting the pre-fabricated devices further comprises the steps of:
d1) temporarily bonding the front-side of the wafer onto a first carrier tape, in a way allowing future release of the wafer there from, with the periphery of the tape fixed by a dicing frame, and affixing the frame and first carrier tape onto a chuck;
d2) while fixing the outer edge of the first carrier tape with a dicing frame, separating and collecting the central portion of the wafer, together with the first carrier tape, from the peripheral portion of the wafer;
d3) temporarily bonding the back-side of the wafer onto a second carrier tape, in a way allowing future release of the wafer there from, and with the outer edge of the second tape fixed by a dicing frame, releasing the first carrier tape from the wafer so as to effect a tape transfer; and
d4) affixing the second carrier tape onto a chuck, with the outer edge of the second carrier tape fixed with a dicing frame, separating and collecting each of the pre-fabricated devices into an ultra thin chip.

16. The method of forming ultra thin chips of claim 15 wherein temporarily bonding the front-side of the wafer onto a first carrier tape further comprises providing a first carrier tape that is UV-releasable.

17. The method of forming ultra thin chips of claim 15 wherein separating the central portion from the peripheral portion of the wafer further comprises traversing a demarcation contour between the central portion and the peripheral portion with a power laser to effect the separation.

18. The method of forming ultra thin chips of claim 15 wherein separating the central portion from the peripheral portion of the wafer further comprises traversing a demarcation contour between the central portion and the peripheral portion with a mechanical cutting head to effect the separation.

19. The method of forming ultra thin chips of claim 15 wherein separating each of the pre-fabricated devices further comprises mechanically dicing apart, with a dicing depth slightly larger than the wafer thickness, the pre-fabricated devices from the wafer.

20. The method of forming ultra thin chips of claim 1 wherein separating and collecting the pre-fabricated devices further comprises the steps of:
d1) temporarily bonding the front-side of the wafer onto a carrier tape, in a way allowing future release of the wafer there from, with the periphery of the carrier tape fixed by a dicing frame, and affixing the frame and carrier tape onto a chuck;
d2) while fixing the outer edge of the carrier tape with the dicing frame, separating each of the pre-fabricated devices by traversing scribe lines between the prefabricated devices with a power laser from wafer backside to effect the separation; and
d3) collecting each of the pre-fabricated devices into an ultra thin chip.

21. The method of forming ultra thin chips of claim 20 wherein separating each of the pre-fabricated devices further comprises utilizing an infrared camera above the wafer backside to detect scribe lines between the prefabricated devices.

22. The method of forming ultra thin chips of claim 20 wherein separating each of the pre-fabricated devices further comprises utilizing a camera underneath a transparent dicing chuck and transparent dicing tape to detect positions of scribe lines between the prefabricated devices.

23. The method of forming ultra thin chips of claim 20 wherein collecting the pre-fabricated devices into ultra thin chips may further comprise transferring the separated devices onto another tape with chip back side adhered on the tape, and picking up each of the pre-fabricated devices into an ultra thin chip.
